(19) United States
(12) Patent Application Publication
(10) Pub. No.: US 2017/0331447 A1
(43) Pub. Date: Nov. 16, 2017

(54) IMPEDANCE DETECTING AND ADJUSTING CIRCUIT

(71) Applicant: Airoha Technology Corp., Hsinchu (TW)

(72) Inventors: Chien-Kuang Lee, Jhubei City (TW); Heng-Chih Lin, Hsinchu City (TW)

(21) Appl. No.: 15/339,964

(22) Filed: Nov. 1, 2016

(30) Foreign Application Priority Data
May 10, 2016 (TW) 105114459

(51) Int. Cl. H03H 7/40; H04B 1/04

(52) U.S. Cl. CPC H03H 7/40; H04B 1/04

(57) ABSTRACT

An impedance detecting and adjusting circuit includes an impedance adjusting unit, a frequency band detection source and a controller. The impedance adjusting unit is disposed in a radio frequency front end device. The radio frequency front end device includes one or more than one transmission port. The frequency band detection source is selectively coupled to the target transmission port of the one or more than one transmission port for transmitting the scan signals having different frequencies to the target transmission port to detect a corresponding operating frequency band of the target transmission port. The controller is coupled to the impedance adjusting unit for adjusting the impedance adjusting unit according to the measured operating frequency band and making the target transmission port achieve impedance matching at least in the operating frequency band thereof.

This application claims the benefit of Taiwan application Serial No. 105114459, filed May 10, 2016, the subject matter of which is incorporated herein by reference.

### BACKGROUND OF THE INVENTION

### Field of the Invention

The invention relates in general to an impedance detecting and adjusting circuit.

### Description of the Related Art

How to reduce the insertion loss during signal transmission or improve the impedance matching between elements has always been a major concern in circuit design. Let the design of an antenna switch be taken for example. The antenna switch has a plurality of transmission ports respectively connected to the signal paths of corresponding frequency bands of the transmission ports, such that one of the transmission ports can be electrically connected to the antenna end to transmit and receive signals. Each transmission port of the antenna switch can be connected to the signal path of a corresponding frequency band of the transmission port. Therefore, each transmission port needs to be designed as a broadband transmission port to cover the operating frequency bands of various applications of telecommunication, such that the insertion loss caused by impedance mismatching can be and accordingly reduced. Even though each transmission port adopts a broadband design, the signal will still have severe insertion loss at high frequencies and such severe insertion loss is disadvantageous to overall power efficiency of the circuit. Additionally, the broadband design normally represents higher design requirements, which will incur higher circuit cost.

Therefore, how to effectively reduce the insertion loss during signal transmission and improve impedance matching between the transmission port and external elements has become a prominent task for the industries.

### SUMMARY OF THE INVENTION

The invention is directed to an impedance detecting and adjusting circuit capable of automatically detecting a corresponding operating frequency band of each transmission port of the radio frequency front end device, and further optimizing the impedance value of the transmission port according to the detection result.

According to an embodiment of the present invention, an impedance detecting and adjusting circuit is provided. The impedance detecting and adjusting circuit includes an impedance adjusting unit, a frequency band detection source and a controller. The impedance adjusting unit is disposed in a radio frequency front end device. The radio frequency front end device includes one or more than one transmission port. The frequency band detection source is selectively coupled to the target transmission port of the one or more than one transmission port for transmitting the scan signals having different frequencies to the target transmission port to detect a corresponding operating frequency band of the target transmission port. The controller is coupled to the impedance adjusting unit for adjusting the impedance adjusting unit according to the measured operating frequency band and making the impedance value of the target transmission port match the operating frequency band thereof.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a simplified block diagram of a circuit system according to an embodiment of the invention.

FIG. 2 is an exemplary curve diagram of insertion loss vs frequency for signals at the transmission port of a radio frequency front end device.

FIGS. 3A˜3F are exemplary circuit diagrams of an impedance adjusting unit according to different embodiments of the invention.

FIG. 4A is a simplified block diagram of an impedance detecting and adjusting circuit implemented in an antenna switch.

FIG. 4B is a simplified block diagram of another example of an impedance detecting and adjusting circuit implemented in an antenna switch.

FIG. 5 is a simplified block diagram of an impedance detecting and adjusting circuit implemented in a power amplifier module.

FIG. 6 is a simplified block diagram of an impedance detecting and adjusting circuit implemented in a low-noise amplifier.

### DETAILED DESCRIPTION OF THE INVENTION

A number of embodiments of the present invention are disclosed below with reference to accompanying drawings, but not every embodiment is illustrated in accompanying drawings. In practical application, the present invention can have different variations and is not limited to the embodiments exemplified in the specification. A number of embodiments are disclosed in the present disclosure to meet the statutory requirements. Designations common to the accompanying drawings are used to indicate identical or similar elements.

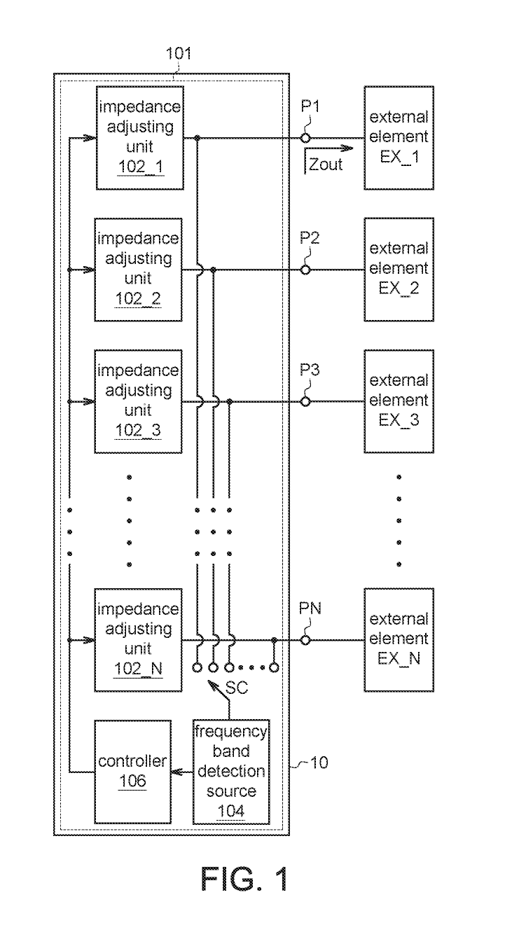

FIG. 1 is a simplified block diagram of a circuit system according to an embodiment of the invention. The circuit system mainly includes a radio frequency front end device 10 and external elements EX_1˜EX_N. The external elements EX_1˜EX_N are electrically connected to one or more than one of transmission ports P1˜PN of the radio frequency front end device 10 to form a plurality of signal paths.

The radio frequency front end device 10 can be realized by an antenna switch, a low-noise amplifier (LNA), a power amplifier module (PAM) or other forms of radio frequency circuit module. The external elements EX_1˜EX_N can be realized by circuit components such as filters operated within a specific frequency band. The radio frequency front end device 10 can feed signals to the external elements EX_1˜EX_N or receive signals from the external elements EX_1˜EX_N through the transmission ports P1˜PN.

Generally speaking, the transmission ports P1˜PN of the radio frequency front end device 10 can be connected to the signal paths having different frequency bands in response to the needs of applications or layout considerations. In terms of the transmission ports P1˜PN, the actual operating frequency band is normally unknown when the radio frequency front end device 10 leaves the factory. For example, the external element EX_1 connected to the transmission port P1 can be a high-frequency filter operated within a frequency band BAND_1 (such as 2300 MHz˜2700 MHz), a medium-frequency filter operated within a frequency band BAND_2 (such as 1700 MHz˜2000 MHz), or a low-frequency filter operated within a frequency band BAND_3 (such as 700 MHz˜900 MHz). Depending on the actual needs, the operating frequency band of the transmission port P1 can be BAND_1, BAND_2 or BAND_3.

To improve the impedance matching between elements, in an embodiment of the invention, the impedance detecting and adjusting circuit 101 detects corresponding operating frequency bands of the transmission ports P1˜PN after the radio frequency front end device 10 is connected to the external elements EX_1˜EX_N, and adaptively adjusts corresponding impedance values of the transmission ports P1˜PN according to the detection result and makes the transmission ports P1˜PN match the corresponding operating frequency band. Here, the said ‘matching’ refers to the insertion loss or the return loss of the signals falls within a tolerable or predetermined range.

As indicated in FIG. 1, the impedance detecting and adjusting circuit 101 includes one or more than one impedance adjusting unit 102_1˜102_N, a frequency band detection source 104 and a controller 106. The impedance adjusting units 102_1˜102_N are disposed in the radio frequency front end device 10, and can be realized by an adjustable matching circuit composed of a capacitive element and/or an inductive element. The impedance adjusting units 102_1˜102_N and the transmission ports P1˜PN form a one-to-one correspondence, such that the impedance values of the transmission ports P1˜PN can be individually adjusted. However, the invention is not limited thereto. In other embodiments, part or all of the impedance adjusting units 102_1˜102_N can be integrated as one impedance adjusting circuit electrically connect to one or more than one transmission port P1˜PN. In the example of FIG. 1, the frequency band detection source 104 and the controller 106 are illustrated in the radio frequency front end device 10, but the invention is not limited thereto, and the frequency band detection source 104 and/or the controller 106 can also be implemented in an external circuit of the radio frequency front end device 10 or a module.

The frequency band detection source 104 can be selectively coupled to the target transmission port Pi of one of the transmission ports P1˜PN (wherein 1≦i≦N), and transmit scan signals SC having different frequencies to the target transmission port Pi to detect the corresponding operating frequency band of the target transmission port Pi. When the frequency band detection source 104 detects frequency band, the internal of the radio frequency front end device 10 is electrically isolated from the target transmission port Pi. For example, an electrical isolation switch (not illustrated) can be disposed between the target transmission port Pi and the corresponding impedance adjusting unit 102_i. The electrical isolation switch will be open-circuited when the frequency band detection source 104 detects the frequency band of the target transmission port Pi, such that the target transmission port Pi is electrically isolated from the impedance adjusting unit 102_i. Or, when the frequency band detection source 104 detects the frequency band of the target transmission port Pi, internal relevant circuit of the radio frequency front end device 10 corresponding to the signal path of the target transmission port Pi will be switched to an off state to avoid the detection result of the frequency band being affected by the internal circuit of the radio frequency front end device 10.

The frequency band detection source 104 can find the corresponding operating frequency band of the target transmission port Pi using various frequency band detecting/scanning technologies. For example, the frequency band detection source 104 can apply a scan signal SC with variable frequency on the target transmission port Pi, and obtain an impedance value Zout of the transmission port at different frequencies according to the voltage or current obtained at the node of the target transmission port Pi. The impedance value Zout is equivalent to the impedance value viewed from the target transmission port Pi towards the external of the radio frequency front end device 10. When the frequency band detection source 104 detects that the corresponding impedance value (such as Zout) of the target transmission port Pi within a specific frequency range is close or equivalent to a specific impedance value, such as 50 Ohm, the said specific frequency range will be regarded as an operating frequency band of the target transmission port Pi.

The controller 106 is coupled to the impedance adjusting units 102_1˜102_N for adjusting the impedance adjusting units 102_1˜102_N according to the measured operating frequency band and making the impedance value of the target transmission port Pi match the specific impedance value within the operating frequency band. For example, the controller 106 adjusts the element reference value of the impedance adjusting unit 102_i according to the measured operating frequency band and makes the impedance value of the target transmission port Pi match to the specific impedance value, such as 50 Ohm within a corresponding operating frequency band.

During impedance adjustment, the target transmission port Pi and the impedance adjusting unit will be switched back to an electrical connection state. For example, the electrical isolation switch (if any) between the target transmission port Pi and the corresponding impedance adjusting unit 102_i will be turned on; or, internal relevant circuit of the radio frequency front end device 10 corresponding to the signal path of the target transmission port Pi will be switched to an ON state. If it is detected that the operating frequency band of the target transmission port Pi falls within a specific frequency range, such as BAND_1, the controller 106 will adjust the element reference value (such as capacitance and/or inductance) of the impedance adjusting unit 102_i and make the target transmission port Pi achieve impedance matching at least in the operating frequency band BAND_1. In an embodiment, the controller 106, based on the measured operating frequency band, can check a look-up table (LUT) to determine the element value of the impedance adjusting unit 102_i. In an embodiment, the controller 106, based on the measured operating frequency band, can dynamically adjust the element value of the impedance adjusting unit 102_i and make the target transmission port Pi close to a best matching state.

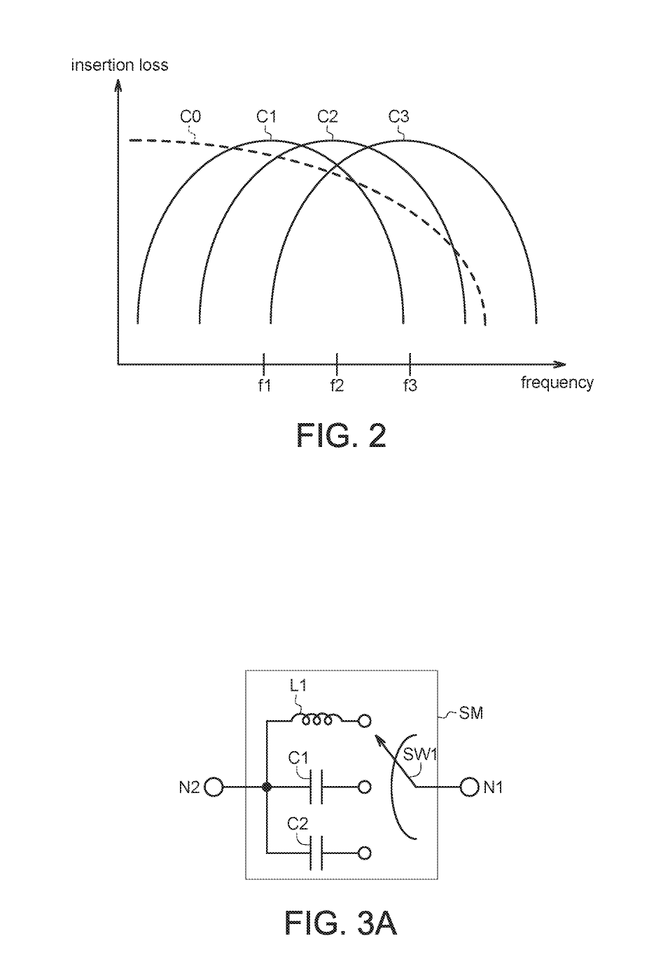

FIG. 2 is an exemplary curve diagram of insertion loss vs frequency for signals at the transmission port of a radio frequency front end device. In the example of FIG. 2, frequencies f1, f2 and f3 respectively represent the center frequencies of different operating frequency bands. As disclosed above, when the transmission port is designed as a broadband transmission port to cover all possible operating frequency bands, the incurred insertion loss will deteriorate as the operating frequency increases. As indicated in curve C0, when the broadband transmission port is operated at a relatively high frequency (such as frequency f3), severe insertion loss will incur and the impedance matching is also poor. Relatively, through the impedance detecting and adjusting mechanism provided in the invention, the transmission port will adaptively match a desired operating frequency band. As indicated in curves C1, C2 and C3, the transmission port can directly match the operating frequency bands whose center frequency is f1, f2 or f3, not only reducing the required frequency bandwidth but further achieving better impedance matching effect within actual operating frequency band.

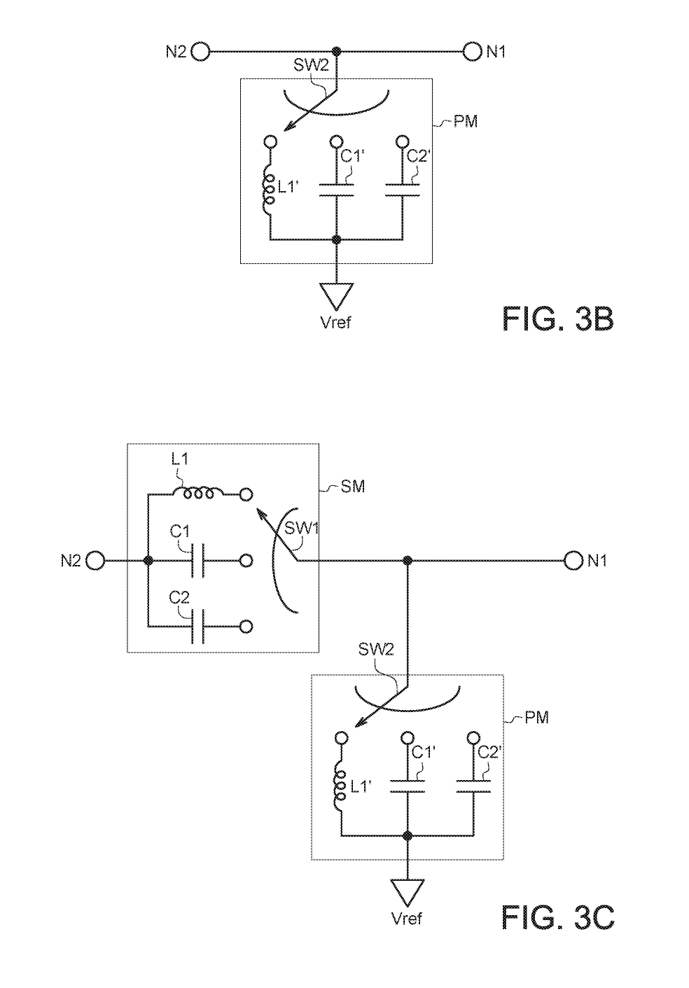

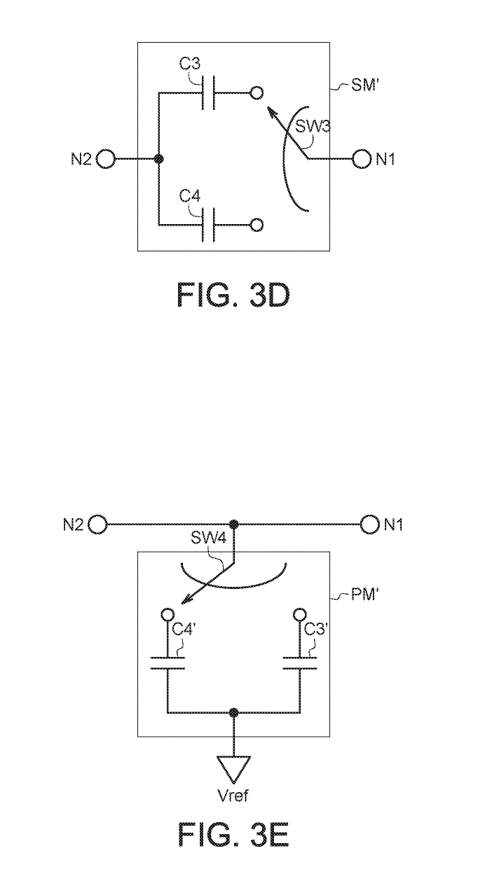

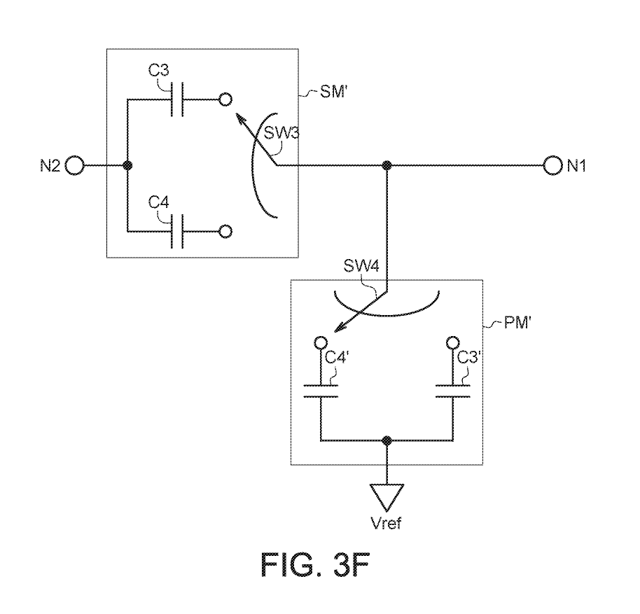

FIGS. 3A˜3F are exemplary circuit diagrams of an impedance adjusting unit according to different embodiments of the invention.

Exemplarily but not restrictively, the said impedance adjusting unit can be any one of the impedance adjusting units 102_1˜102_N of FIG. 1.

In the example of FIG. 3A, the impedance adjusting unit includes a series adjusting module SM connected in series between the nodes N1 and N2. The node N1 (or the node N2) can be realized by such as the target transmission port Pi. The node N2 (or the node N1) can be realized by such as the internal circuit node of the radio frequency front end device 10 connected to the impedance adjusting unit 102_i.

As indicated in FIG. 3A, the series adjusting module SM may include one or more than one series capacitor (such as capacitors C1 and C2), one or more than one series inductor (such as inductor L1), and a series switch SW1. The series switch SW1, in response to the control of the controller (such as controller 106), makes the node N1 (such as the target transmission port Pi) electrically connected to the node N2 selectively through the series capacitors C1 or C2 or the series inductor L1 (such as the internal node of the radio frequency front end device 10) to adjust the impedance value of the target transmission port Pi. In an embodiment, the series adjusting module SM may include one or more than one series inductor and the series switch SW1 only but not any series capacitor.

In the example of FIG. 3B, the impedance adjusting unit includes a parallel adjusting module PM connected in parallel between the nodes N1 and N2. As indicated in FIG. 3B, the parallel adjusting module PM may include one or more than one parallel capacitor (such as capacitor C1′ and C2′), one or more than one parallel inductor (such as inductor L1′) and a parallel switch SW2. The parallel switch SW2, in response to the control of the controller (such as controller 106), makes the node N1 (such as the target transmission port Pi) electrically connected to the reference voltage Vref (such as the ground voltage) selectively through the parallel capacitors C1′ or C2′ or the parallel inductor L1′ to adjust the impedance value of the target transmission port Pi. In an embodiment, the parallel adjusting module PM may include one or more than one parallel inductor and the parallel switch SW2 only but not any parallel capacitor.

In the example of FIG. 30, the impedance adjusting unit coupled between the nodes N1 and N2 include both the series adjusting module SM and the parallel adjusting module PM. The controller (such as controller 106) can adjust the impedance value of the target transmission port Pi by suitably adjusting the series switch SW1 and the parallel switch SW2.

In the example of FIG. 3D, the impedance adjusting unit includes a series adjusting module SM′ composed of a capacitive element and a switch element only but not any inductive element. As indicated in FIG. 3D, the series adjusting module SM′ includes a plurality of series capacitors (such as capacitor C3 and C4) and a series switch SW3. The series switch SW3, in response to the control of the controller (such as controller 106), makes the node N1 (such as the target transmission port Pi) electrically connected to the node N2 (such as the internal node of the radio frequency front end device 10) selectively through the series capacitor C3 or C4 to adjust the impedance value of the target transmission port Pi.

In the example of FIG. 3E, the impedance adjusting unit includes a parallel adjusting module PM′ composed of a capacitive element and a switch element only but not any inductive element. As indicated in FIG. 3E, the parallel adjusting module PM′ includes a plurality of parallel capacitors (such as capacitor C3′ and C4′) and a parallel switch SW4. The parallel switch SW4, in response to the control of the controller (such as controller 106), makes the node N1 (such as the target transmission port Pi) electrically connected to a reference voltage Vref (such as ground voltage) selectively through the parallel capacitor C3′ or C4′ to adjust the impedance value of the target transmission port Pi.

In the example of FIG. 3F, the impedance adjusting unit coupled between the nodes N1 and N2 includes both the series adjusting module SM′ and the parallel adjusting module PM′. The controller (such as controller 106) can adjust the impedance value of the target transmission port Pi by suitably controlling the series switch SW3 and the parallel switch SW4.

It should be understood that the invention is not limited to the above exemplifications. The quantity and disposition of capacitors and inductors in the series/parallel connection adjusting module can be adjusted according to the needs in actual application. To summarize, any design of adjusting the impedance value of the target transmission port Pi by changing the reference values of the capacitive elements and/or inductive elements on the signal path of the target transmission port Pi are within the spirit of the invention.

According to an embodiment of the invention, the impedance detecting and adjusting circuit can be realized by an antenna switch, a low-noise amplifier, a power amplifier module or other forms of radio frequency circuit module. The impedance detecting and adjusting circuit is elaborated below with accompanying drawings.

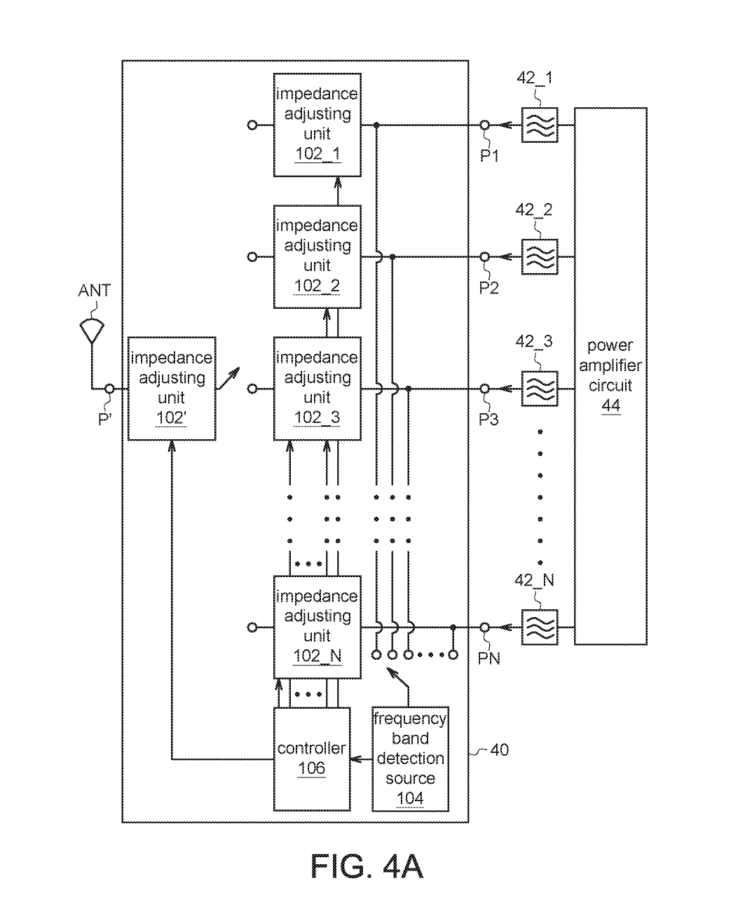

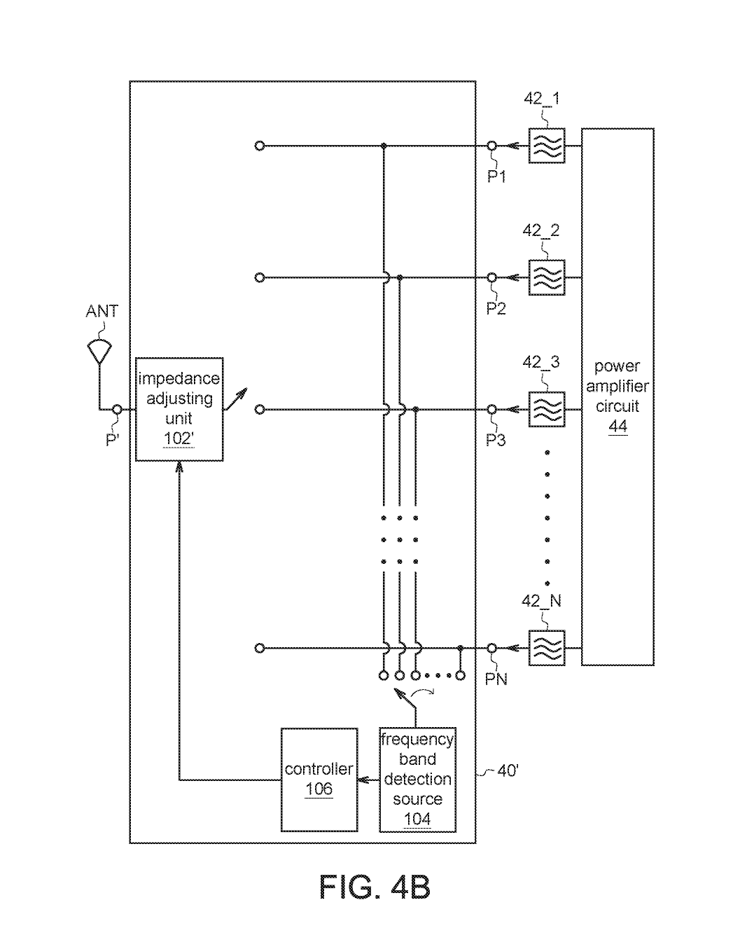

FIG. 4A is a simplified block diagram of an impedance detecting and adjusting circuit implemented in an antenna switch 40. For the convenience of description, designations common to FIG. 4A and above embodiments are used to indicate identical or similar elements.

The antenna switch 40 includes transmission ports P1˜PN and an antenna port P′. The transmission ports P1˜PN are connected to filters (or duplexers) 42_1˜42_N each having a corresponding operating frequency band. The antenna port P′ is connected to the antenna ANT. The filters (or duplexers) 42_1˜42_N, for example, are connected to the power amplifier circuit 44 to transmit the signals corresponding to the operating frequency band. The antenna port P′ can be selectively connected to one of the transmission ports P1˜PN to receive and transmit signals through the corresponding signal paths. For example, when the antenna port P′ is switched to be connected to the transmission port P1, the signals outputted from the power amplifier circuit 44 can be transmitted through the antenna

ANT via the filter (or duplexer) 42_1, the transmission port P1 and the antenna port P′. Relatively, the signals received from the antenna ANT can be transmitted to the transceiver (not illustrated in the diagram) via the antenna port P′, the transmission port P1, and the filter (or duplexer) 42_1.

In the example of FIG. 4A, the impedance detecting and adjusting circuit includes impedance adjusting units 102_1˜102_N, a frequency band detection source 104 and a controller 106. The impedance detecting and adjusting circuit may selectively include an impedance adjusting unit 102′. The impedance adjusting unit 102′ is coupled to the antenna port P′, and can be selectively coupled to any one of the transmission ports P1˜PN. Exemplarily but not restrictively, the impedance adjusting unit 102′ can be realized by a combination of the said capacitive elements and/or inductive elements as indicated in FIGS. 3A˜3C.

The frequency band detection source 104 can detect frequency bands of the transmission ports P1˜PN to find corresponding operating frequency bands of the transmission ports P1˜PN. For example, when the filter (or duplexer) 42_1 connected to the transmission port P1 is a bandpass filter whose operating frequency band is BAND_1, the frequency band detection source 104 can determine that the corresponding operating frequency band of the transmission port P1 is BAND_1 using the said frequency band detection mechanism.

After the operating frequency band of the transmission port P1 is detected, the controller 106 can adjust the element reference value of the impedance adjusting unit 102_1 and/or the impedance adjusting unit 102′ according to the measured operating frequency band and make the transmission port P1 achieve impedance matching in the operating frequency band BAND_1.

FIG. 4B is a simplified block diagram of another example of an impedance detecting and adjusting circuit implemented in an antenna switch 40′. The present embodiment is different from previous embodiments mainly in that the signal paths of the transmission ports P1˜PN do not have corresponding impedance adjusting units 102_1˜102_N disposed thereon, and the impedance values of the transmission ports P1˜PN are collectively adjusted by the impedance adjusting unit 102′.

For example, suppose the corresponding operating frequency bands of the transmission port P1 and P2 respectively are BAND_1 and BAND_2. When the transmission port P1 is electrically connected to the antenna port P′, the controller 106 can adjust the element reference value of the impedance adjusting unit 102′ according to the measured operating frequency band BAND_1 and make the transmission port P1 achieve impedance matching in the operating frequency band BAND_1. Then, when the transmission port P2 is electrically connected to the antenna port P′, the controller 106 can adjust the element reference value of the impedance adjusting unit 102′ according to the operating frequency band BAND_2 of the transmission port P2 and make the transmission port P2 achieve impedance matching in the operating frequency band BAND_2.

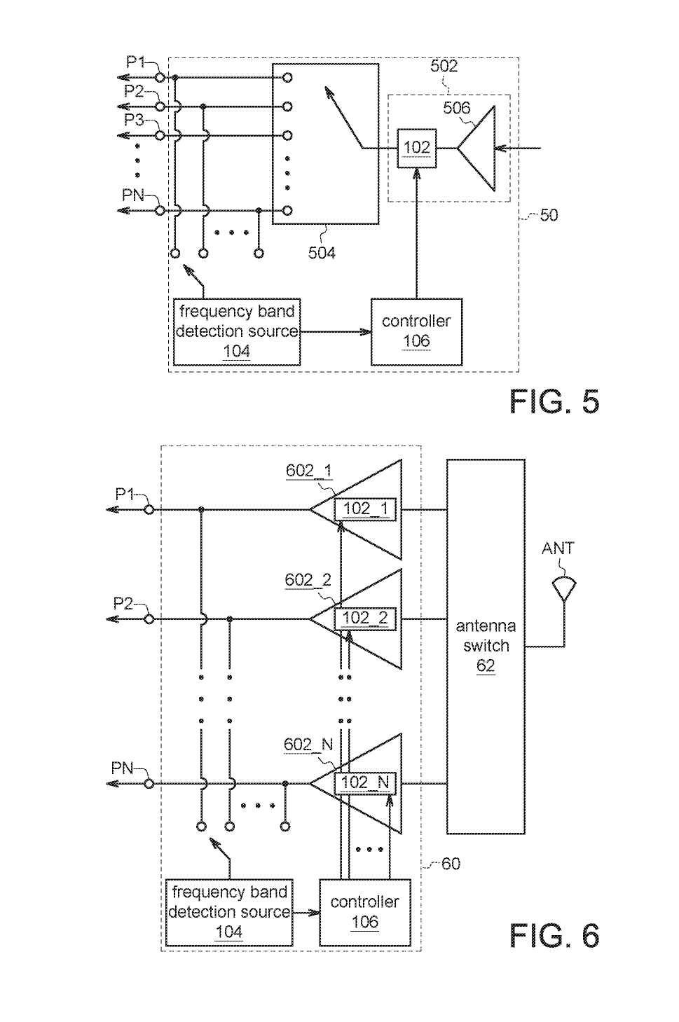

FIG. 5 is a simplified block diagram of an impedance detecting and adjusting circuit implemented in a power amplifier nodule 50. For the convenience of description, designations common to FIG. 5 and above embodiments are used to indicate identical or similar elements.

The power amplifier module 50 includes a power amplifier circuit 502 and a switch 504. The power amplifier circuit 502 includes a power amplifier 506 and an impedance adjusting unit 102 coupled to the output end of the power amplifier 506. The power amplifier circuit 502 can convert the signal of the input end into an output signal having a larger power, and further selectively transmit the output signal to one of the ports P1˜PN using the switch 504. Exemplarily but not restrictively, the impedance adjusting unit 102 can be realized by a combination of the said capacitive elements and/or inductive elements as indicated in FIGS. 3A˜3C.

When the switch 504 electrically connects the output end of the power amplifier circuit 502 to one of the transmission ports P1˜PN (that is, the target transmission port Pi), the frequency band detection source 104 will scan the frequency of the target transmission port Pi to find a corresponding operating frequency band of the target transmission port Pi. Then, the controller 106 can adjust the element reference value of the impedance adjusting unit 102 according to the measured operating frequency band and make the target transmission port Pi achieve impedance matching in the operating frequency band thereof.

FIG. 6 is a simplified block diagram of an impedance detecting and adjusting circuit implemented in a low-noise amplifier 60. For the convenience of description, designations common to FIG. 6 and above embodiments are used to indicate identical or similar elements.

The low-noise amplifier circuit 60 is electrically connected to the antenna switch 62. The antenna switch 62 outputs the signals received through the antenna ANT to the low-noise amplifier circuit 60. The signals, having been amplified by the low-noise amplifier circuit 60, are outputted through the corresponding transmission ports P1˜PN.

The low-noise amplifier circuit 60 includes one or more than one of the low-noise amplifiers 602_1˜602_N for amplifying the signals received from the antenna ANT and reducing their own noise as much as possible. The low-noise amplifier 602_1˜602_N include the impedance adjusting units 102_1˜102_N controlled by the controller 106. The impedance adjusting units 102_1˜102_N can adjust the impedance values at the output ends of the low-noise amplifiers 602_1˜602_N, that is, the impedance values of the transmission ports P1˜PN. When the frequency band detection source 104 detects the corresponding operating frequency bands of the transmission ports P1˜PN, the controller 106, based on the measured operating frequency band, will adjust the element reference values of the impedance adjusting units 102_1˜102_N and make the transmission ports P1˜PN achieve impedance matching in the corresponding operating frequency bands thereof.

To summarize, the impedance detecting and adjusting circuit provided in the invention automatically detects corresponding operating frequency band of each transmission port of the radio frequency front end device, and further optimizes the impedance value of the transmission port according to the detection result, not only reducing the required frequency bandwidth but further providing optimized impedance matching for different operating frequency bands.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An impedance detecting and adjusting circuit, comprising:
an impedance adjusting unit disposed in a radio frequency front end device, wherein the radio frequency front end device comprises one or more than one transmission port;
a frequency band detection source selectively coupled to a target transmission port of the one or more than one transmission port for transmitting scan signals having different frequencies to the target transmission port to detect a corresponding operating frequency band of the target transmission port; and
a controller coupled to the impedance adjusting unit for adjusting the impedance adjusting unit according to the detected operating frequency band and making the target transmission port achieve impedance matching at least in the operating frequency band.

2. The impedance detecting and adjusting circuit according to claim 1, wherein the impedance adjusting unit is coupled to the one or more than one transmission port.

3. The impedance detecting and adjusting circuit according to claim 1, wherein the frequency band detection source detects the corresponding operating frequency band of the target transmission port when the internal of the radio frequency front end device is electrically isolated from the target transmission port.

4. The impedance detecting and adjusting circuit according to claim 1, wherein the controller adjusts the impedance adjusting unit according to the detected operating frequency band and makes the impedance value of the target transmission port match 50 Ohm within the operating frequency band.

5. The impedance detecting and adjusting circuit according to claim 1, wherein the impedance adjusting unit comprises:
a series adjusting module connected in series between the target transmission port and an internal node of the radio frequency front end device, wherein the series adjusting module comprises:
at least one series capacitor;
at least one series inductor; and
a series switch, in response to the control of the controller, making the target transmission port electrically connected to the internal node selectively through the at least one series capacitor or the at least one series inductor.

6. The impedance detecting and adjusting circuit according to claim 1, wherein the impedance adjusting unit comprises:
a parallel adjusting module connected in parallel between the target transmission port and an internal node of the radio frequency front end device, wherein the parallel adjusting module comprises:
at least one parallel capacitor;
at least one parallel inductor; and
a parallel switch, in response to the control of the controller, making the target transmission port electrically connected to a reference voltage selectively through the at least one parallel capacitor or the at least one parallel inductor.

7. The impedance detecting and adjusting circuit according to claim 1, wherein the impedance adjusting unit comprises:
a series adjusting module connected in series between the target transmission port and an internal node of the radio frequency front end device, wherein the series adjusting module comprises:
at least one series capacitor;
at least one series inductor; and
a series switch, in response to the control of the controller, making the target transmission port electrically connected to the internal node selectively through the at least one series capacitor or the at least one series inductor; and
a parallel adjusting module connected in parallel between the target transmission port and the internal node, wherein the parallel adjusting module comprises:
at least one parallel capacitor;
at least one parallel inductor; and
a parallel switch, in response to the control of the controller, making the target transmission port electrically connected to a reference voltage selectively through the at least one parallel capacitor or the at least one parallel inductor.

8. The impedance detecting and adjusting circuit according to claim 1, wherein the impedance adjusting unit comprises:
a series adjusting module connected in series between the target transmission port and an internal node of the radio frequency front end device, wherein the series adjusting module comprises:
at least one series capacitor; and
a series switch, in response to the control of the controller, making the target transmission port electrically connected to the internal node selectively through the at least one series capacitor.

9. The impedance detecting and adjusting circuit according to claim 1, wherein the impedance adjusting unit comprises:
a parallel adjusting module connected in parallel between the target transmission port and an internal node of the radio frequency front end device, wherein the parallel adjusting module comprises:
at least one parallel capacitor; and
a parallel switch, in response to the control of the controller, making the target transmission port electrically connected to a reference voltage selectively through the at least one parallel capacitor.

10. The impedance detecting and adjusting circuit according to claim 1, wherein the impedance adjusting unit comprises:
a series adjusting module connected in series between the target is transmission port and an internal node of the radio frequency front end device, wherein the series adjusting module comprises:
at least one series capacitor; and
a series switch, in response to the control of the controller, making the target transmission port electrically connected to the internal node selectively through the at least one series capacitor; and
a parallel adjusting module connected in parallel between the target transmission port and an internal node of the radio frequency front end device, wherein the parallel adjusting module comprises:
at least one parallel capacitor; and
a parallel switch, in response to the control of the controller, making the target transmission port electrically connected to a reference voltage selectively through the at least one parallel capacitor.

11. The impedance detecting and adjusting circuit according to claim 1, wherein the radio frequency front end device is an antenna switch.

12. The impedance detecting and adjusting circuit according to claim 11, wherein the impedance adjusting unit is coupled to an antenna port of the antenna switch and selectively coupled to any one of the one or more than one transmission port.

13. The impedance detecting and adjusting circuit according to claim 1, wherein the radio frequency front end device is a low-noise amplifier (LNA).

14. The impedance detecting and adjusting circuit according to claim 1, wherein the radio frequency front end device is a power amplifier module (PAM).

15. The impedance detecting and adjusting circuit according to claim 1, wherein the impedance adjusting unit comprises:
a series adjusting module connected in series between the target transmission port and an internal node of the radio frequency front end device, wherein the series adjusting module comprises:
at least one series inductor; and
a series switch, in response to the control of the controller, making the target transmission port electrically connected to the internal node selectively through the at least one series inductor.

16. The impedance detecting and adjusting circuit according to claim 1, wherein the impedance adjusting unit comprises:
a parallel adjusting module connected in parallel between the target transmission port and an internal node of the radio frequency front end device, wherein the parallel adjusting module comprises:
at least one parallel inductor; and
a parallel switch, in response to the control of the controller, making the target transmission port electrically connected to a reference voltage selectively through the at least one parallel inductor.
